(19) United States
(12) Patent Application Publication
(10) Pub. No.: US 2025/0017116 A1
(43) Pub. Date: Jan. 9, 2025

(54) MAGNETIC MEMORY DEVICE USING MAGNON SPIN VALVE INCLUDING TOPOLOGICAL MATERIAL AND EXCHANGE COUPLING

(71) Applicants: POSTECH RESEARCH AND BUSINESS DEVELOPMENT FOUNDATION, Pohang-si (KR); KOREA ADVANCED INSTITUTE OF SCIENCE AND TECHNOLOGY, Daejeon (KR); The Industry & Academic Cooperation in Chungnam National University, Daejeon (KR)

(72) Inventors: Hyungyu JIN, Pohang-si (KR); Jong Ryul JEONG, Daejeon (KR); Kab-Jin KIM, Daejeon (KR); Sangjun PARK, Pohang-si (KR); JunSeok KIM, Pohang-si (KR); Cao Van PHUOC, Daejeon (KR)

(73) Assignees: POSTECH RESEARCH AND BUSINESS DEVELOPMENT FOUNDATION, Pohang-si (KR); KOREA ADVANCED INSTITUTE OF SCIENCE AND TECHNOLOGY, Daejeon (KR); The Industry & Academic Cooperation in Chungnam National University, Daejeon (KR)

(21) Appl. No.: 18/750,151

(22) Filed: Jun. 21, 2024

(30) Foreign Application Priority Data
Jul. 4, 2023 (KR) 10-2023-0086640

(51) Int. Cl. H10N 50/10; H01F 10/32; H10B 61/00; H10N 50/85

(52) U.S. Cl. CPC H10N 50/10; H01F 10/3268; H10B 61/22; H10N 50/85

(57) ABSTRACT

According to an embodiment of the inventive concept, a magnetic memory device includes a substrate on which a transistor controlled by a word line is disposed, a spin detection layer disposed on the substrate, and a magnon spin valve disposed on the spin detection layer. Here, the magnon spin valve includes a free layer disposed on the spin detection layer, a reference layer disposed on the free layer, and a spacer disposed between the free layer and the reference layer. Also, one edge of the spin detection layer is connected to a source/drain region of the transistor, the other edge of the spin detection layer is connected to a source line, and the magnon spin valve is disposed on a portion between the one edge and the other edge of the spin detection layer. The spin detection layer includes a topological material or a weyl semimetal. Each of the reference layer and the free layer includes a ferromagnetic insulator.

### CROSS-REFERENCE TO RELATED APPLICATIONS

This U.S. non-provisional patent application claims priority under 35 U.S.C. § 119 of Korean Patent Application No. 10-2023-0086640, filed on Jul. 4, 2023, the entire contents of which are hereby incorporated by reference.

### BACKGROUND

The present disclosure relates to a semiconductor device, and more particularly, to a magnetic memory device including a magnon spin valve.

This research has been conducted with the support of the Samsung Future Technology Promotion Project (project number: SRFC-MA2002-02).

Due to speed improvement and low power consumption of an electronic device, a demand for speed improvement and/or a low operating voltage of a semiconductor memory device contained in the electric device is increasing. In order to satisfy the above-described requirements, a magnetic memory device has been suggested as a semiconductor memory device. Since the magnetic memory device has characteristics such as a high-speed operation and/or non-volatility, the magnetic memory device is being spotlighted as a next-generation semiconductor memory device.

In general, the magnetic memory device may include a magnetic tunnel junction pattern. The magnetic tunnel junction pattern may include two magnetic materials and an insulating film disposed therebetween. The magnetic tunnel junction pattern may have a resistance value that is varied depending on magnetization directions of the two magnetic materials. For example, when the magnetization directions of the two magnetic materials are anti-parallel to each other, the magnetic tunnel junction pattern may have a large resistance value, and when the magnetization directions of the two magnetic materials are parallel to each other, the magnetic tunnel junction pattern may have a small resistance value. Data may be written/read by using differences between the resistance values.

As an electronics industry is developed, a demand for high integration and/or low power consumption of the magnetic memory device is intensifying. Thus, various research is being conducted to satisfy the above-described demand.

### SUMMARY

The present disclosure provides a magnon spin valve-based magnetic memory device having improved reliability.

An embodiment of the inventive concept provides a magnetic memory device including: a substrate on which a transistor controlled by a word line is disposed; a spin detection layer disposed on the substrate; and a magnon spin valve disposed on the spin detection layer. Here, the magnon spin valve includes: a free layer disposed on the spin detection layer; a reference layer disposed on the free layer; and a spacer disposed between the free layer and the reference layer. Also, one edge of the spin detection layer is connected to a source/drain region of the transistor, the other edge of the spin detection layer is connected to a source line, the magnon spin valve is disposed on a portion between the one edge and the other edge of the spin detection layer, the spin detection layer includes a topological material or a weyl semimetal, and each of the reference layer and the free layer includes a ferromagnetic insulator.

In an embodiment, the ferromagnetic insulator may include R₃Fe₅O₁₂ or MFe₂O₄. Here, R may be Y, Pr, Nd, Sm, Eu, Gd, Tb, Dy, Ho, Er, Tm, Yb or Lu, and M may be Fe, Mn, Zn, Cu, Ni, Mg or Co.

In an embodiment, the weyl semimetal may include one of WTe₂₋ₓ or MoTe₂₋ₓ. Here, a range of x may be 0≤x≤1.

In an embodiment, the topological insulator may include one of Bi₁₋ₓSbₓ, (BiₓSb₁₋ₓ)₂Te₃, Bi₂Se₃, or Sb₂Te₃. Here, a range of x may be 0≤x≤1.

In an embodiment, the magnetic memory device may further include an exchange coupling layer spaced apart from the spacer with the reference layer therebetween. Here, the exchange coupling layer may include a ferromagnetic insulator or an antiferromagnetic insulator.

In an embodiment, the magnetic memory device may further include an insulating layer disposed between the free layer and the spin detection layer. Here, the insulating layer may include an antiferromagnetic insulator or paramagnetic insulator

In an embodiment, the reference layer may have a thickness greater than that of the free layer.

In an embodiment, the substrate may be a silicon substrate, a germanium substrate, or a silicon-germanium substrate.

In an embodiment of the inventive concept, a magnetic memory device includes: a spin detection layer; a magnon spin valve disposed on the spin detection layer; an antiferromagnetic insulating layer disposed between the spin detection layer and the magnon spin valve; and an exchange coupling layer disposed on the magnon spin valve. Here, the spin detection layer includes a topological insulator or a weyl semimetal, the magnon spin valve includes: a free layer spaced apart from the spin detection layer with the antiferromagnetic insulating layer therebetween; a reference layer disposed on the free layer, in which the reference layer contacts the exchange coupling layer; and a spacer disposed between the free layer and the exchange coupling layer, each of the free layer and the reference layer includes a ferromagnetic insulator, and the exchange coupling layer includes an antiferromagnetic insulator or a ferromagnetic insulator.

In an embodiment, the ferromagnetic insulator may include R₃Fe₅O₁₂ or MFe₂O₄. Here, R may be Y, Pr, Nd, Sm, Eu, Gd, Tb, Dy, Ho, Er, Tm, Yb or Lu, and M may be Fe, Mn, Zn, Cu, Ni, Mg or Co.

In an embodiment, the weyl semimetal may include one of WTe₂₋ₓ or MoTe₂₋ₓ. Here, a range of x may be 0≤x≤1.

In an embodiment, the topological insulator may include one of Bi₁₋ₓSbₓ, (BiₓSb₁₋ₓ)₂Te₃, Bi₂Se₃, or Sb₂Te₃. Here, a range of x may be 0≤x≤1.

In an embodiment of the inventive concept, a magnetic memory device includes: a word line extending in a first direction; a bit line and a source line each extending in a second direction crossing the first direction; and a memory cell. Here, the memory cell includes: a spin detection layer having a first side connected to the source line and a second side opposite to the first side; a magnon spin valve disposed on a portion of the spin detection layer between the first side and the second side of the spin detection layer; and a transistor connected between the bit line and the second side of the spin detection layer and controlled by the word line. Also, the spin detection layer includes a topological insulator or a weyl semimetal, the magnon spin valve includes: a free layer disposed on the spin detection layer; a reference layer disposed on the free layer; and a spacer disposed between the free layer and the reference layer, and each of the free layer and the reference layer includes a ferromagnetic insulator.

In an embodiment, the ferromagnetic insulator may include R₃FeO₁₂ or MFe₂O₄. Here, R may be Y, Pr, Nd, Sm, Eu, Gd, Tb, Dy, Ho, Er, Tm, Yb or Lu, and M may be Fe, Mn, Zn, Cu, Ni, Mg or Co.

In an embodiment, the weyl semimetal may include one of WTe₂₋ₓ or MoTe₂₋ₓ. Here, a range of x may be 0≤x≤1.

In an embodiment, the topological insulator may include one of Bi₁₋ₓSbₓ, (BiₓSb₁₋ₓ)₂Te₃, Bi₂Se₃, or Sb₂Te₃. Here, a range of x may be 0≤x≤1.

In an embodiment, the magnetic memory device may further include an exchange coupling layer spaced apart from the spacer with the reference layer therebetween. Here, the exchange coupling layer may include a ferromagnetic insulator or an antiferromagnetic insulator.

In an embodiment, the magnetic memory device may further include an antiferromagnetic insulator disposed between the free layer and the spin detection layer.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a schematic circuit diagram representing a memory cell of a magnetic memory device according to an embodiment of the inventive concept;

FIG. 2 is a schematic cross-sectional view illustrating the magnetic memory device according to an embodiment of the inventive concept;

FIG. 3 is an enlarged cross-sectional view illustrating region aa of FIG. 2;

FIG. 4 is an enlarged cross-sectional view illustrating the region aa of FIG. 2;

FIGS. 5 and 6 are schematic views illustrating a writing operation of the magnetic memory device;

FIGS. 7 and 8 are schematic views illustrating a reading operation of the magnetic memory device;

FIG. 9 is a schematic cross-sectional view illustrating the magnetic memory device according to some embodiments;

FIG. 10 is a view illustrating an observed voltage according to a magnetic field of the magnetic memory device according to an embodiment; and

FIG. 11 is a view illustrating an observed voltage according to a magnetic field of a magnetic memory device according to a comparative example.

### DETAILED DESCRIPTION

Hereinafter, preferred embodiments of the inventive concept will be described in detail with reference to the attached drawings.

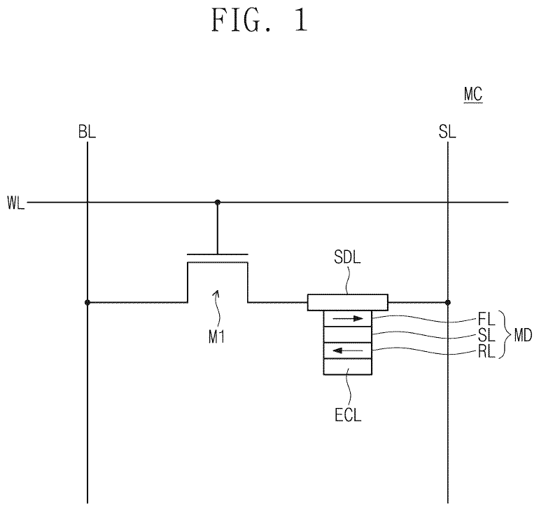

FIG. 1 is a schematic circuit diagram representing a memory cell of a magnetic memory device according to an embodiment of the inventive concept.

Referring to FIG. 1, a memory cell MC of the magnetic memory device may include a word line WL, a bit line BL, a source line SL, a transistor M1, a magnon spin valve MD, and a spin detection layer SDL.

The transistor M1 of the memory cell MC may be connected between the bit line BL and one edge of the spin detection layer SDL. A gate electrode of the transistor M1 may be connected to the word line WL. The transistor M1 may control an electrical connection between the spin detection layer SDL and the bit line BL.

The bit line BL may be connected to a sense amplifier (not shown). The sense amplifier may compare a sensing voltage of the bit line BL with a reference voltage to output data stored in the memory cell MC.

The source line SL may be connected to the other edge of the spin detection layer SDL.

The magnon spin valve MD may be disposed on the spin detection layer SDL. The magnon spin valve MD may be disposed on a portion between the one edge and the other edge of the spin detection layer SDL.

As illustrated in FIG. 1, the magnon spin valve MD may include a free layer FL, a reference layer RL, and a spacer SL disposed therebetween. The free layer FL may be disposed between the spin detection layer SDL and the spacer SL, and the reference layer RL may be spaced apart from the free layer FL with the spacer SL disposed therebetween. An exchange coupling layer ECL may be additionally provided on the reference layer RL. The exchange coupling layer ECL may be spaced apart from the spacer SL with the reference layer RL disposed therebetween. A detailed description on the magnon spin valve MD will be described later.

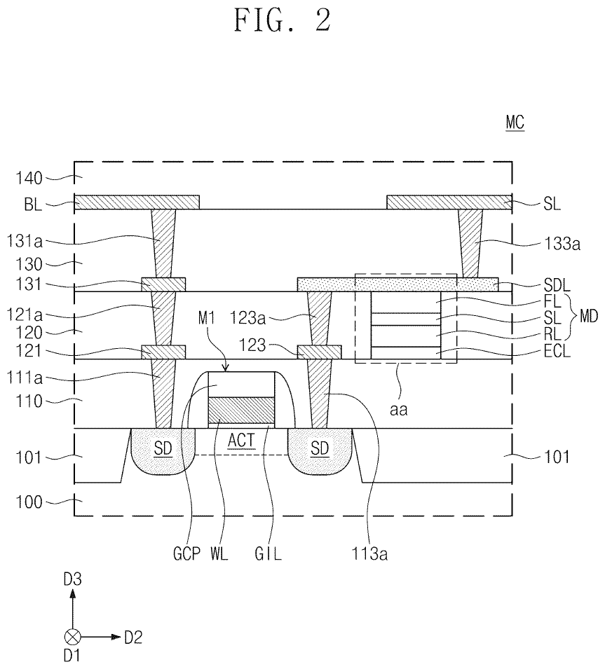

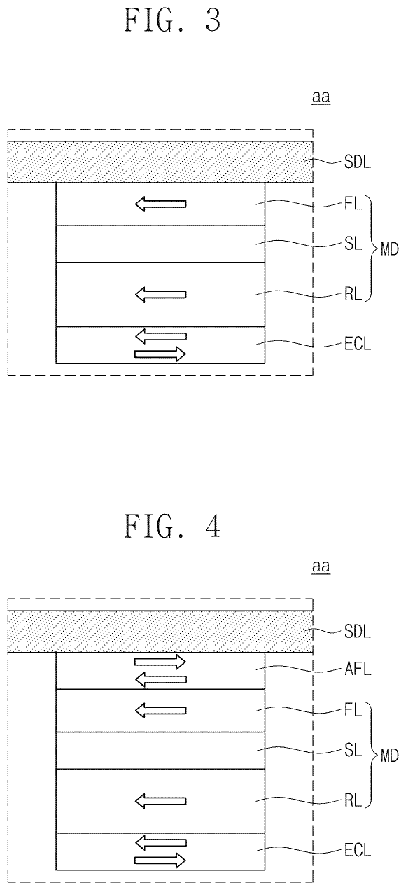

FIG. 2 is a schematic cross-sectional view illustrating the magnetic memory device according to an embodiment of the inventive concept. FIG. 3 is an enlarged cross-sectional view illustrating region aa of FIG. 2.

Referring to FIG. 2, a semiconductor substrate 100 including a cell region may be provided. The semiconductor substrate 100 may be a silicon substrate, a germanium substrate, and/or a silicon-germanium substrate. The semiconductor substrate 100 may include an active pattern ACT doped with impurities. The active pattern ACT may extend along a first direction D1 parallel to a top surface of the semiconductor substrate 100. When a plurality of active patterns ACT are provided, the active patterns ACT may be parallel to the top surface of the semiconductor substrate 100 and spaced apart from each other in a second direction D2 crossing the first direction D1.

A device isolation pattern 101 may be disposed on a side surface of the active pattern ACT. When the plurality of active patterns ACT are provided, the device isolation pattern 101 may be disposed between the active patterns ACT. The device isolation pattern 101 may include, e.g., a silicon oxide film, a silicon oxynitride film, or a silicon nitride film.

The word line WL may be disposed on the semiconductor substrate 100. A gate dielectric layer GIL may be disposed between the word line WL and the semiconductor substrate 100. A gate capping pattern GCP may be disposed on the word line WL.

The word line WL may include at least one of a semiconductor material doped with a dopant (e.g., doped silicon), metal (e.g., tungsten, aluminum, titanium and/or tantalum), a conductive metal nitride (e.g., titanium nitride, tantalum nitride, and/or tungsten nitride), and a metal-semiconductor compound (e.g., metal silicide). For example, the gate dielectric layer GIL may include a high dielectric material. The gate capping pattern GCP may include an insulating material such as silicon oxide or silicon nitride. The word line WL may pass through the active pattern ACT and extend in the first direction D1.

Source/drain patterns SD may be disposed on the active pattern ACT at both sides of the word line WL. The source/drain patterns SD may include impurities having a conductivity type opposite to that of the active pattern ACT. According to some embodiments, the source/drain patterns SD may be made of a semiconductor material having a lattice constant different from that of the active pattern ACT. The source/drain patterns SD may include silicon carbide or silicon germanium. A metal silicide film (not shown) may be disposed on the source/drain patterns SD. In embodiments, the source/drain patterns SD and the word line WL may constitute the transistor M1 of the memory cell.

A first interlayer insulating film 110 may be disposed on the top surface of the semiconductor substrate 100. The first interlayer insulating film 110 may cover the word line WL and the source/drain patterns SD. The first interlayer insulating film 110 may be made of, e.g., oxide nitride or oxynitride.

First and second active contacts 111a and 113a may pass through the first interlayer insulating layer 110 and be connected to the source/drain patterns SD, respectively. The first and second active contacts 111a and 113a may include a barrier metal pattern and a metal pattern. The first and second active contacts 111a, 113a may include, e.g., metal such as tungsten, titanium, tantalum, and cobalt and/or conductive metal nitride such as titanium nitride, tantalum nitride, and tungsten nitride.

A silicide pattern (not shown) may be disposed between the first and second active contacts 111a and 113a and between the source/drain patterns. The silicide pattern may include metal-silicide. For example, the silicide pattern may include at least one of titanium-silicide, tantalum-silicide, tungsten-silicide, nickel-silicide, and cobalt-silicide.

A first lower conductive pattern 121, second lower conductive patterns 123, and the magnon spin valve MD may be disposed on the first interlayer insulating film 110. The first lower conductive pattern 121 may be connected to the first active contact 111a, and the second lower conductive pattern 123 may be connected to the second active contact 113a.

Referring to FIGS. 2 and 3 together, the magnon spin valve MD may include the reference layer RL, the spacer SL, and the free layer FL, which are sequentially laminated on the first interlayer insulating film 110. The exchange coupling layer ECL may be disposed between the reference layer RL and the first interlayer insulating layer 110.

The free layer FL may have a first surface and a second surface opposite the first surface, the first surface may contact the spacer SL, and the second surface may contact the spin detection layer SDL. The free layer FL may have a magnetization direction that is variable by the spin detection layer SDL. The free layer FL may have vertical magnetic anisotropy or horizontal magnetic anisotropy. The free layer FL may be deformed into a single layer structure or a multi-layer structure. The free layer FL may include a ferromagnetic insulator. The free layer FL may include an iron garnet or inverse spinel-based material group. The free layer FL may include, e.g., R₃Fe₅O₁₂, or MFe₂O₄. Here, R may be Y, Pr, Nd, Sm, Eu, Gd, Tb, Dy, Ho, Er, Tm, Yb, or Lu. Here, M may be Fe, Mn, Zn, Cu, Ni, Mg, or Co.

The reference layer RL may have a magnetization direction fixed to one direction and have perpendicular magnetic anisotropy or horizontal magnetic anisotropy. The reference layer RL may have one surface that contacts the spacer SL. The reference layer RL may include a ferromagnetic insulator. The reference layer RL may include an iron garnet or inverse spinel-based material group. The reference layer RL may include, e.g., R₃Fe₅O₁₂, or MFe₂O₄. Here, R may be Y, Pr, Nd, Sm, Eu, Gd, Tb, Dy, Ho, Er, Tm, Yb, or Lu. Here, M may be Fe, Mn, Zn, Cu, Ni, Mg, or Co.

The spacer SL may include an antiferromagnetic insulator or a paramagnetic insulator. The spacer SL may include a rock salt oxide, corundum, or perovskite-based material group. The spacer SL may include, e.g., NiO, Cr₂O₃, Fe₂O₃, or BiFeO₃.

The spin detection layer SDL may have one side and the other side disposed opposite thereto. The spin detection layer SDL may have the one side connected to the transistor M1 and the other side connected to the source line SL. The spin detection layer SDL may apply a spin orbit torque or magnon-mediated spin torque to the free layer FL of the magnon spin valve MD. The spin detection layer SDL may have a portion that contacts the free layer FL. The spin detection layer SDL may induce switching of the free layer FL by using a spin Hall effect (SHE) when in-plane current flows in the spin detection layer SDL adjacent to the free layer FL. The spin detection layer SDL may include a topological insulator or a weyl semimetal. The topological insulator may include Bi₁₋ₓSbₓ, (BiₓSb₁₋ₓ)₂Te₃, Bi₂Se₃, Sb₂Te₃, and the weyl semimetal may include WTe₂₋ₓ or MoTe₂₋ₓ (0≤x≤1).

The exchange coupling layer ECL may contact the other surface of the reference layer RL, which is disposed opposite to one surface of the reference layer RL. The exchange coupling layer ECL may be spaced apart from the spacer SL with the reference layer RL interposed therebetween. The exchange coupling layer ECL may include a ferromagnetic insulator or an antiferromagnetic insulator. The exchange coupling layer ECL may include a inverse spinel, rock salt oxide, or perovskite-based material group. The spacer ECL may include, e.g., MFe₂O₄, NiO, CoO, Cr₂O₃, Fe₂O₃, or BiFeO₃. Here, M may be Fe, Mn, Zn, Cu, Ni, Mg, or Co.

The reference layer RL and the exchange coupling layer ECL may provide exchange coupling. Specifically, the reference layer RL may have a magnetization direction that is fixed by the exchange coupling layer ECL. The magnetization direction of the reference layer RL may be parallel or anti-parallel to an in-plane magnetization direction of the exchange coupling layer ECL adjacent to the reference layer RL.

Each of the spin detection layer SDL and the spacer SL may have a thickness greater than 0 nm and equal to or less than 10 nm. The exchange coupling layer ECL may have a thickness equal to or greater than 10 nm and equal to or less than 30 nm or less. The free layer FL may have a thickness greater than 30 nm and less than 90 nm. The thickness of the reference layer RL may be greater than the thickness of the free layer FL.

A second interlayer insulating film 120 covering the magnon spin valve MD, the exchange coupling layer ECL, and the first and second lower conductive patterns 121 and 123 may be disposed on the first interlayer insulating film 110. The second interlayer insulating film 120 may be made of, e.g., oxide nitride or oxynitride.

A first lower contact plug 121a and a second lower contact plug 123a may pass through the second interlayer insulating film 120 and be connected to the first lower conductive pattern 121 and the second lower conductive pattern 123, respectively.

An upper conductive pattern 131 and the spin detection layer SDL may be disposed on the second interlayer insulating film 120. The upper conductive pattern 131 may be connected to the first lower contact plug 121a. The spin detection layer SDL may be connected to one edge of the second lower contact plug 123a. The spin detection layer SDL may be disposed on the magnon spin valve MD. The spin detection layer SDL may have a width in the second direction D2 greater than that of the magnon spin valve MD in the second direction D2. The spin detection layer SDL may contact the free layer FL.

A third interlayer insulating film 130 covering the upper conductive pattern 131 and the spin detection layer SDL may be provided. The second interlayer insulating film 130 may be made of, e.g., oxide nitride or oxynitride.

A first upper contact plug 131a and a second upper contact plug 133a may pass through the third interlayer insulating film 130 and be connected to the first upper conductive pattern 131 and the spin detection layer SDL, respectively. The second upper contact plug 133a may be connected to the other edge of the spin detection layer SDL. In terms of a plane, the magnon spin valve MD may be disposed between the second upper contact plug 133a and the second lower contact plug 123a.

The bit line BL and the source line SL may be disposed on the third interlayer insulating film 130. The bit line BL and the source line SL may each extend in the second direction D2. The bit line BL may be connected to the first upper contact plug 131a. The source line SL may be connected to the spin detection layer SDL through the second upper contact plug 133a. Although the bit line BL and the source line SL are disposed at the same level in FIG. 2, the bit line BL and the source line SL may be disposed at different levels.

A fourth interlayer insulating film 140 covering the bit line BL and the source line SL may be provided. The fourth interlayer insulating film 140 may be made of, e.g., oxide nitride or oxynitride.

FIG. 4 is an enlarged cross-sectional view illustrating portion aa of FIG. 2, showing the magnon spin valve of the magnetic memory device according to some embodiments.

Referring to FIG. 4, according to some embodiments, the magnetic memory device may further include an antiferromagnetic insulating layer AFL disposed between the free layer FL and the spin detection layer SDL. The free layer FL may be spaced apart from the spin detection layer SDL with the antiferromagnetic insulating layer AFL therebetween. The antiferromagnetic insulating layer AFL may have one surface that is in contact with the spin detection layer SDL and the other surface that is in contact with the free layer FL. The antiferromagnetic insulating layer AFL may include an antiferromagnetic insulator. The antiferromagnetic insulating layer AFL may include a rock salt oxide, corundum, or perovskite-based material group. The antiferromagnetic insulating layer AFL may include, e.g., NiO, CoO, Cr₂O₃, Fe₂O₃, or BiFeO₃. According to some embodiments, instead of an antiferromagnetic insulating layer, a paramagnetic insulating layer may be provided.

### [Writing Process]

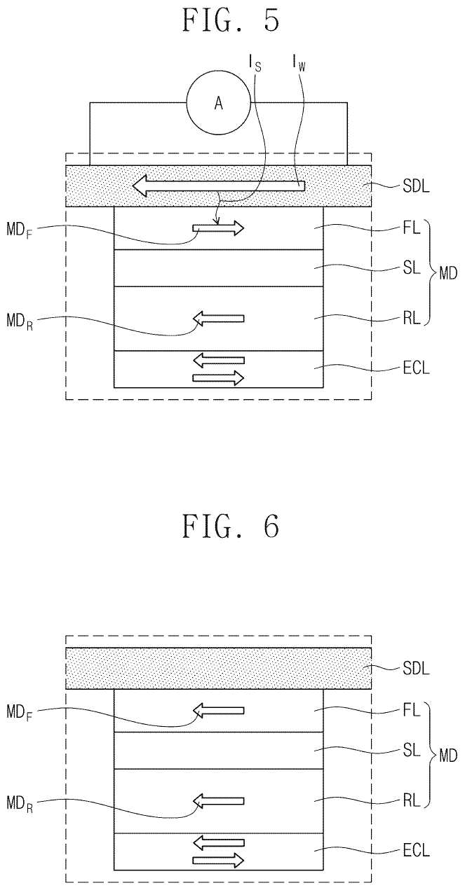

FIGS. 5 and 6 are schematic views illustrating a writing operation of the magnetic memory device. Referring to FIG. 5, the reference layer RL may have a magnetization direction MD_{R} fixed to one direction. The free layer FL may have the magnetization direction MD_{F} that is variable to be parallel or anti-parallel to the magnetization direction MD_{R} of the reference layer RL. The magnetization directions MD_{R} and MD_{F} of the reference layer RL and the free layer FL may be substantially parallel to an interface of the spacer SL.

Write current IW may flow through the spin detection layer SDL between the source line SL and the source/drain pattern SD. The write current Iw may flow adjacent to and parallel to an interface between the spin detection layer SDL and the magnon spin valve MD. The write current IW flowing through the spin detection layer SDL is converted into spin current Is in a direction perpendicular to the interface by the spin Hall effect (SHE). The spin current Is may flow in a direction perpendicular to an interface between the spin detection layer SDL and the free layer FL, and the spin current Is arrives at the free layer FL. The spin current Is arrived at the free layer FL may reverse the magnetization direction of the free layer FL as illustrated in FIG. 6 when a spin direction of the spin current Is and the magnetization direction MD_{F} of the free layer FL are opposite to each other. The magnetization direction MD_{F} of the free layer FL may be switched to be anti-parallel (or parallel) to the magnetization direction MD_{R} of the reference layer RL. Through this process, the writing process is completed, and writing from an on-state to an off-state and writing from the off-state to the on-state may be achieved by reversing the direction of the write current flowing through the spin detection layer SDL.

According to an embodiment of the inventive concept, as the spin detection layer SDL includes a material having a large spin Hall angle such as the topological insulator, a critical current density required for the switching of the magnetization direction MD_{F} of the free layer FL may decrease.

### [Reading Process]

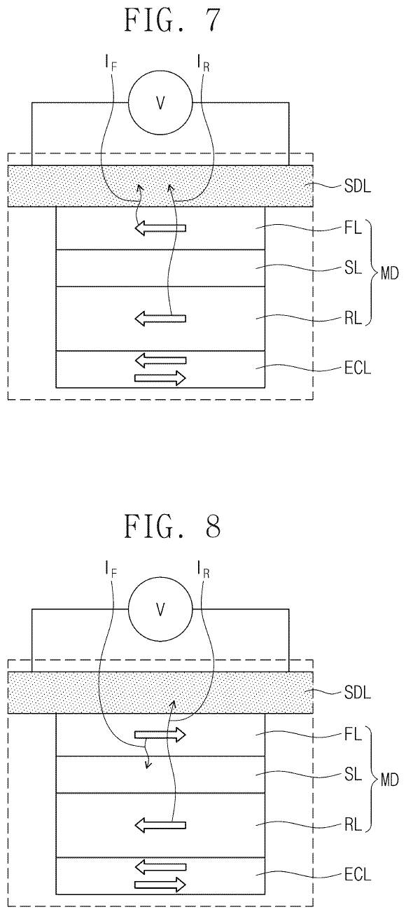

Referring to FIGS. 7 and 8, heat or an electromagnetic wave may be applied to the magnon spin valve MD. In this case, magnon current I_{F} and I_{R} may be generated in the free layer FL and reference layer RL. The magnon current I_{F} and I_{R} may be converted into an observable voltage by an inverse spin Hall effect in the spin detection layer SDL. Current that generates Joule heating may not flow in the magnon spin valve MD.

A resistance state of the magnon spin valve MD may be detected by voltage observation. Whether the magnon spin valve MD is in a high-resistance state or a low-resistance state may be determined by the voltage observation.

For example, as illustrated in FIG. 7, when the magnetization direction MD_{F} of the free layer FL is parallel to the magnetization direction MD_{R} of the reference layer RL, the magnon spin valve MD may be in the low-resistance state. When the magnetization direction MD_{F} of the free layer FL is parallel to the magnetization direction MD_{R} of the reference layer RL, the magnon current I_{F} generated in the free layer FL and the magnon current I_{R} generated in the reference layer RL may be added, and thus large magnon current may be arrived at the spin detection layer SDL.

As another example, as illustrated in FIG. 8, when the magnetization direction MD_{F} of the free layer FL is anti-parallel to the magnetization direction MD_{R} of the reference layer RL, the magnon spin valve MD may be in the high-resistance state. When the magnetization direction MD_{F} of the free layer FL is anti-parallel to the magnetization direction MD_{R} of the reference layer RL, the magnon current I_{F} generated in the free layer FL and the magnon current I_{R} generated in the reference layer RL may be canceled by each other, and thus extremely small or no magnon current may be arrived at the spin detection layer SDL.

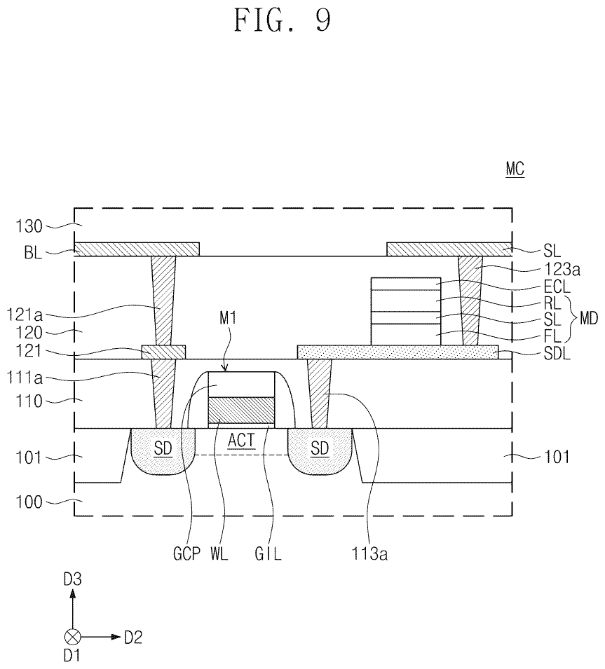

FIG. 9 is a schematic cross-sectional view illustrating the magnetic memory device according to some embodiments. Hereinafter, a redundant description will be omitted because features except for those described below are substantially the same as those described in FIGS. 1 to 8.

Referring to FIGS. 1 and 9, a first lower conductive pattern 121 and a spin detection layer SDL may be disposed on a first interlayer insulating film 110. The first lower conductive pattern 121 may be connected to a first active contact 111a. The spin detection layer SDL may have one edge connected to a second active contact 113a.

A magnon spin valve MD may be disposed on the spin detection layer SDL. An exchange coupling layer ECL may be disposed between the magnon spin valve MD and the spin detection layer SDL.

A second interlayer insulating film 120 may cover the first lower conductive pattern 121, the spin detection layer SDL, the magnon spin valve MD, and the exchange coupling layer ECL.

A first lower contact plug 121a and a second lower contact plug 123a may pass through the second interlayer insulating film 120 and be connected to the first upper conductive pattern 121 and the spin detection layer SDL, respectively. The second lower contact plug 123a may be connected to the other edge of the spin detection layer SDL. In terms of the plane, the magnon spin valve MD may be disposed between a second active contact 113a and the second lower contact plug 123a.

A bit line BL and a source line SL may be disposed on the second interlayer insulating film 120. The bit line BL and the source line SL may each extend in the second direction D2. The bit line BL may be connected to the first lower contact plug 121a. The source line SL may be connected to the spin detection layer SDL through the second lower contact plug 123a. Although the bit line BL and the source line SL are disposed at the same level in FIG. 9, the bit line BL and the source line SL may be disposed at different levels.

A third interlayer insulating film 130 covering the bit line BL and the source line SL may be provided. In the magnetic memory device according to some embodiments, the spin detection layer SDL may be provided, and then the magnon spin valve MD may be provided.

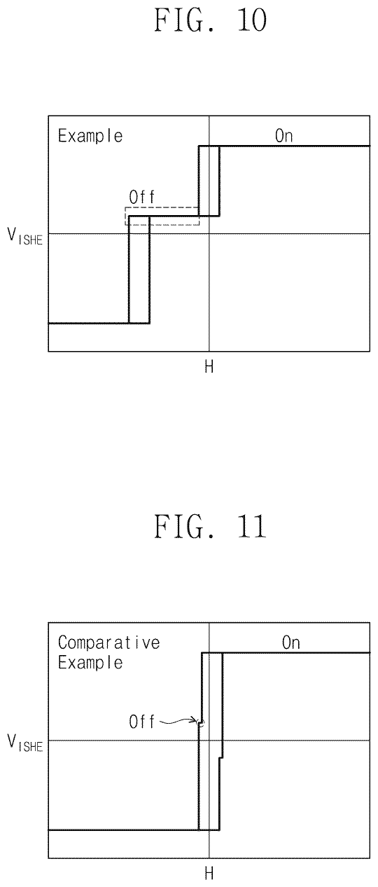

FIG. 10 is a view illustrating an observed voltage according to a magnetic field of the magnetic memory device according to an embodiment. FIG. 11 is a view illustrating an observed voltage according to a magnetic field of a magnetic memory device according to a comparative example.

The magnetic memory device according to the comparative example has the same condition except that the exchange coupling layer ECL is omitted in the embodiment. In both of the embodiment and the comparative example, the free layer and the reference layer use the same ferromagnetic insulator material.

Referring to FIG. 10, the reference layer RL may provide exchange coupling with the exchange coupling layer ECL to secure a margin in an off-state, thereby enabling stable operation. The reference layer RL may have large magnetic anisotropy in one direction and maintain the existing magnetization direction even in a state in which the magnetization of the free layer FL is reversed to realize the more stable off-state.

Referring to FIG. 11, on the contrary, in the magnetic memory device according to the comparative example, the off-state is not clearly shown compared to the on-state. The spin current applied to change the magnetization of the free layer FL during the writing process may be arrived at the free layer FL to change the magnetization direction of the free layer FL.

That is, reliability of the magnetic memory device according to an embodiment of the inventive concept may increase by using the exchange coupling of the reference layer RL.

The magnetic memory device according to an embodiment of the inventive concept has following advantages.

First, in the magnetic memory device according to an embodiment of the inventive concept, all layers including the free layer and the reference layer of the magnon spin valve may be made of an insulator. Typical MRAM (e.g., STT-MRAM and SOT-MRAM) includes a free layer and a reference layer made of metal or an alloy material. Due to the above-described difference, the magnetic memory device according to an embodiment of the inventive concept may be free from Joule heating because no charge current flows through the magnon spin valve. Thus, energy loss may be reduced, and a temperature of the magnetic memory element may be prevented from increasing excessively.

Second, in the magnetic memory device according to an embodiment of the inventive concept, the spin detection layer may change the magnetization of the free layer and convert the magnon current into the observable voltage at the same time. Also, the spin detection layer made of the topological insulator (or weyl semimetal) has a large spin Hall angle. In case of the inverse spin Hall effect of converting the magnon current into the observable voltage, a greater voltage may be generated by using the spin detection layer even when the same magnon current is introduced. As another comparative example, when a metal electrode layer is disposed on the reference layer, and the source line is connected to the metal electrode layer instead of the spin detection layer, the spin detection layer may perform a write function, and the metal electrode layer may perform a read function. According to the comparative example, detection of a read signal may be extremely lower in the metal electrode layer than in the spin detection layer made of the topological insulator (or weyl semimetal). That is, a magnitude of the read signal of the magnetic memory device according to an embodiment of the inventive concept may be amplified compared to the corresponding comparative example. Also, the spin detection layer may convert even small magnon current into a large voltage. Thus, although the magnetic layer (e.g., the free layer and the reference layer) having a polycrystalline structure is provided to generate small magnon current, the spin detection layer may serve as the magnon spin valve. As a result, both single crystal and polycrystalline magnetic layers may be used in a process of manufacturing the magnetic layer.

Third, the magnetic memory device according to the embodiment of the inventive concept may include the antiferromagnetic insulating layer between the spin detection layer and the free layer (refer to FIG. 4). As the antiferromagnetic insulating layer is inserted therebetween, the magnetization direction of the free layer may be switched by magnon-mediated spin torque instead of the spin orbit torque (SOT). While the spin torque is a process of being transferred to a material having a different spin of an electron through the spin current to change a magnetization direction of the material, the magnon-mediated spin torque may be performed through an interaction between the electron and the magnon. In this process, the direction of the magnetization of the magnetic material can be controlled by the magnons. Also, as the antiferromagnetic insulator having a proper thickness is inserted between the free layer and the spin detection layer, a spin mixing conductance increases may increase to obtain a large signal. The spin mixing conductance is a parameter that affects an efficiency of the spin current at an interface between two magnetic materials. Also, since the antiferromagnetic insulating layer serves as a buffer layer for spin detection layer deposition, the spin detection layer may have an improved performance when provided on the antiferromagnetic insulating layer instead of being provided directly on the free layer made of the ferromagnetic insulator.

According to the embodiment of the inventive concept, the magnetic memory device may include the spin detection layer having one edge connected to the source/drain region of the transistor and the other edge connected to the source line. The magnon spin valve that is entirely made of the insulator may be disposed on the spin detection layer. The spin detection layer may include the material such as the topological insulator with the large spin hall angle. Thus, the critical current density required for switching of the magnon spin valve may decrease. In addition, the magnetic memory device according to the embodiment of the inventive concept includes the exchange coupling layer disposed adjacent to the reference layer of the magnon spin valve. The reference layer may maintain the existing magnetization direction although the state in which the magnetization of the free layer is reversed, thereby realizing more stable operation through exchanging and coupling with the exchange coupling layer.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. A magnetic memory device comprising:
a substrate on which a transistor controlled by a word line is disposed;
a spin detection layer disposed on the substrate; and
a magnon spin valve disposed on the spin detection layer,
wherein the magnon spin valve comprises:
a free layer disposed on the spin detection layer;
a reference layer disposed on the free layer; and
a spacer disposed between the free layer and the reference layer,
wherein one edge of the spin detection layer is connected to a source/drain region of the transistor,
the other edge of the spin detection layer is connected to a source line,
the magnon spin valve is disposed on a portion between the one edge and the other edge of the spin detection layer,
the spin detection layer comprises a topological material or a weyl semimetal, and
each of the reference layer and the free layer comprises a ferromagnetic insulator.

2. The magnetic memory device of claim 1, wherein the ferromagnetic insulator comprises R₃Fe₅O₁₂ or MFe₂O₄,
wherein R is Y, Pr, Nd, Sm, Eu, Gd, Tb, Dy, Ho, Er, Tm, Yb or Lu, and M is Fe, Mn, Zn, Cu, Ni, Mg or Co.

3. The magnetic memory device of claim 1, wherein the weyl semimetal comprises one of WTe₂₋ₓ or MoTe₂₋ₓ,
wherein a range of x is 0≤x≤1.

4. The magnetic memory device of claim 1, wherein the topological insulator comprises one of Bi₁₋ₓSbₓ, (BiₓSb₁₋ₓ)₂Te₃, Bi₂Se₃, or Sb₂Te₃,
wherein a range of x is 0≤x≤1.

5. The magnetic memory device of claim 1, further comprising an exchange coupling layer spaced apart from the spacer with the reference layer therebetween,
wherein the exchange coupling layer comprises a ferromagnetic insulator or an antiferromagnetic insulator.

6. The magnetic memory device of claim 1, further comprising an insulating layer disposed between the free layer and the spin detection layer,
wherein the insulating layer comprises an antiferromagnetic insulator or paramagnetic insulator.

7. The magnetic memory device of claim 1, wherein the reference layer has a thickness greater than that of the free layer.

8. The magnetic memory device of claim 1, wherein the substrate is a silicon substrate, a germanium substrate, or a silicon-germanium substrate.

9. A magnetic memory device comprising:
a spin detection layer;
a magnon spin valve disposed on the spin detection layer;
an antiferromagnetic insulating layer disposed between the spin detection layer and the magnon spin valve; and
an exchange coupling layer disposed on the magnon spin valve,
wherein the spin detection layer comprises a topological insulator or a weyl semimetal,
the magnon spin valve comprises:
a free layer spaced apart from the spin detection layer with the antiferromagnetic insulating layer therebetween;
a reference layer disposed on the free layer, wherein the reference layer contacts the exchange coupling layer; and
a spacer disposed between the free layer and the exchange coupling layer,
each of the free layer and the reference layer comprises a ferromagnetic insulator, and
the exchange coupling layer comprises an antiferromagnetic insulator or a ferromagnetic insulator.

10. The magnetic memory device of claim 9, wherein the ferromagnetic insulator comprises R₃Fe₅O₁₂ or MFe₂O₄, wherein R is Y, Pr, Nd, Sm, Eu, Gd, Tb, Dy, Ho, Er, Tm, Yb or Lu, and M is Fe, Mn, Zn, Cu, Ni, Mg or Co.

11. The magnetic memory device of claim 9, wherein the weyl semimetal comprises one of WTe₂₋ₓ or MoTe₂₋ₓ,
wherein a range of x is 0≤x≤1.

12. The magnetic memory device of claim 9, wherein the topological insulator comprises one of Bi₁₋ₓSbₓ, (BiₓSb₁₋ₓ)₂Te₃, Bi₂Se₃, or Sb₂Te₃,
wherein a range of x is 0≤x≤1.

13. A magnetic memory device comprising:
a word line extending in a first direction;
a bit line and a source line each extending in a second direction crossing the first direction; and
a memory cell,
wherein the memory cell comprises:
a spin detection layer having a first side connected to the source line and a second side opposite to the first side;
a magnon spin valve disposed on a portion of the spin detection layer between the first side and the second side of the spin detection layer; and
a transistor connected between the bit line and the second side of the spin detection layer and controlled by the word line,
wherein the spin detection layer comprises a topological insulator or a weyl semimetal,
the magnon spin valve comprises:
a free layer disposed on the spin detection layer;
a reference layer disposed on the free layer; and
a spacer disposed between the free layer and the reference layer, and
each of the free layer and the reference layer comprises a ferromagnetic insulator.

14. The magnetic memory device of claim 13, wherein the ferromagnetic insulator comprises R₃Fe₅O₁₂ or MFe₂O₄,
wherein R is Y, Pr, Nd, Sm, Eu, Gd, Tb, Dy, Ho, Er, Tm, Yb or Lu, and M is Fe, Mn, Zn, Cu, Ni, Mg or Co.

15. The magnetic memory device of claim 13, wherein the weyl semimetal comprises one of WTe₂₋ₓ or MoTe₂₋ₓ,
wherein a range of x is 0≤x≤1.

16. The magnetic memory device of claim 13, wherein the topological insulator comprises one of Bi₁₋ₓSbₓ, (BiₓSb₁₋ₓ)₂Te₃, Bi₂Se₃, or Sb₂Te₃,
wherein a range of x is 0≤x≤1.

17. The magnetic memory device of claim 13, further comprising an exchange coupling layer spaced apart from the spacer with the reference layer therebetween,
wherein the exchange coupling layer comprises a ferromagnetic insulator or an antiferromagnetic insulator.

18. The magnetic memory device of claim 13, further comprising an antiferromagnetic insulator disposed between the free layer and the spin detection layer.
